(19) United States
(12) Patent Application Publication
(10) Pub. No.: US 2012/0031472 A1
(43) Pub. Date: Feb. 9, 2012

(54) Support for Photovoltaic Module and Photovoltaic Module

(75) Inventors: Palvin Chee Leong Chan, Seattle, WA (US); Yu Wang, New District Wuxi (CN); Lang Guo, New District Wuxi (CN); Xili Jiao, New District Wuxi (CN)

(73) Assignee: WUXI SUNTECH POWER CO., LTD, New District Wuxi (CN)

(21) Appl. No.: 13/197,101

(22) Filed: Aug. 3, 2011

(30) Foreign Application Priority Data
Aug. 3, 2010 (CN) 201010252429.1

(51) Int. Cl. H01L 31/048; H01L 23/12

(52) U.S. Cl. 136/251; 248/310

(57) ABSTRACT

The present invention discloses a photovoltaic module and a support thereof. The photovoltaic module comprises a photovoltaic cell laminate and a support adapted to be mounted onto an installation surface. The support is connected to a back surface of the photovoltaic cell laminate and comprises a first connecting portion close to a front side of the photovoltaic cell laminate and a second connecting portion disposed close to a back side of the photovoltaic cell laminate. When a plurality of photovoltaic modules is mounted onto the installation surface, the first connecting portion of one photovoltaic module is engaged with the second connecting portion of another adjacent photovoltaic module, so that a relative position of the photovoltaic module and another adjacent photovoltaic module is maintained and the plurality of photovoltaic modules is mounted onto the installation surface.

### CLAIM OF FOREIGN PRIORITY

The present application claims priority to Chinese Patent Application No. 201010252429.1, filed Aug. 3, 2010, which is hereby incorporated by reference in its entirety.

### FIELD OF THE INVENTION

The present invention relates to solar photovoltaic application, and particularly to a support for a photovoltaic module and a photovoltaic module having the same.

### BACKGROUND OF THE INVENTION

Today, energy shortage is a widespread problem all over the world. As a result, a number of new, sustainable energy sources have gained much attention. People are paying more and more attention to the use of solar energy. Compared to other energy sources, solar cells as an energy device have many advantages in terms of cleanliness and environmental protection. Consequently, solar cells are more and more widely applied. Solar photovoltaic power generation is very important to alleviate the current energy crisis and to improve the ecological environment. The solar cell is made from a material which is able to generate a photovoltaic effect, such as silicon, gallium arsenide, copper indium selenium or other materials so as to convert sunlight into electricity by the photovoltaic effect. Currently, a photovoltaic module made up of a plurality of solar cells has been put into use widely, for example, the photovoltaic modules are applied to construct a power generation system, or are used as a building wall or mounted on rooftop of buildings.

US Patent Application Publication Nos. 2009/0320905A1, 2009/0320906A1 and 2009/0320907A1 which are correlative to each other and assigned to the same corporation, SunPower Corp., disclose a photovoltaic module adapted to be mounted onto rooftop of buildings. The photovoltaic module comprises a photovoltaic laminate and a frame wherein the photovoltaic laminate is encased. The frame includes opposite leading and trailing frame members and opposite first and second frame members. These four frame members are separately formed, respectively, and they are assembled together by a set of connectors so as to form a frame encompassing the perimeter of the photovoltaic laminate.

In addition, a first arm, a second arm, a third arm and a fourth arm are formed in the frame. The first and third arms are respectively formed at opposite ends of the first side frame member, and the second and fourth arms are respectively formed at opposite ends of the second side frame member. The first and second arms extend outwardly beyond the leading frame member, and the third and fourth arms extend outwardly beyond the trailing frame member. The first and second arms are identical in configuration, and the third and fourth arms are identical in configuration. These four arms can make the photovoltaic module effectuate a tilted orientation relative to a substantially flat surface. Mounting regions are respectively formed on the four arms. A lateral space between the first and second arms is less than the one between the third and fourth arms. When adjacent two photovoltaic modules are required to be connected with each other in a front-to-back direction, the first and second arms of the first photovoltaic module are disposed between the third and fourth arms of the second photovoltaic module, and the mounting regions formed on the first and third arms are respectively aligned with the mounting regions formed on the second and fourth arms. Then by means of cooperation between male connectors and female connectors, the adjacent two photovoltaic modules are thus assembled end to end with each other. Furthermore, when adjacent two photovoltaic modules are required to be connected side by side with each other in a left-to-right direction, the first and second photovoltaic modules are aligned with each other, in detail, the second arm of the first photovoltaic module and the first arm of the second photovoltaic module, as well as the fourth arm of the first photovoltaic module and the third arm of the second photovoltaic module, are respectively aligned, and then, similarly by means of cooperation between male connectors and female connectors, the adjacent two photovoltaic modules are thus assembled side by side with each other. However, such a photovoltaic module has a relative more complex connecting manner. Moreover, regardless of a front-to-back arrangement or a side-by-side arrangement, such a photovoltaic module needs additional male and female connectors to complete the connection of the photovoltaic modules. Such a connecting manner would increase the number of parts, thereby increasing cost and complicating assembling procedure; this is contrary to the improvement of working efficiency. Furthermore, this will make it more difficult to repair the photovoltaic system too.

Moreover, the photovoltaic module employing the above-mentioned frame will result in an increase of the manufacturing cost and of the weight of the whole photovoltaic module, which will restrict the application of the photovoltaic module on building rooftops having a limited bearing load, thereby hindering the large-scale extended applications of the photovoltaic module.

Therefore, it is necessary to provide an improved photovoltaic module to fix the above technical problem in the prior art and to reduce weight of the photovoltaic module so as to facilitate installation and repair processes.

### SUMMARY OF THE INVENTION

The main objectives of the present invention are to provide a support for a photovoltaic module and a photovoltaic module having the same, which are simple in structure and will facilitate installation and repair.

To achieve the above objectives, an aspect of the present invention is to provide a photovoltaic module comprising a photovoltaic cell laminate and a support adapted to be mounted onto an installation surface. The support includes a supporting portion defining a support face for supporting a back surface of the photovoltaic cell laminate, a first connecting portion integrally extending from said supporting portion in a first direction and close to a front side of the photovoltaic cell laminate and a second connecting portion integrally extending from said supporting portion in a second direction opposite to said first direction and disposed close to a back side of the photovoltaic cell laminate. When a plurality of photovoltaic modules are mounted onto the installation surface, the first connecting portion of one photovoltaic module is overlappingly connected with the second connecting portion of another adjacent photovoltaic module so that a relative position of the photovoltaic module and another adjacent photovoltaic module is maintained and orientation and installation of the photovoltaic system are performed.

Another aspect of the present invention is to provide a support for a photovoltaic module, which is adapted to be mounted onto an installation surface to support a photovoltaic cell laminate of a photovoltaic module. The support defines a supporting portion adapted for supporting a back surface of the photovoltaic cell laminate and comprises a first connecting portion integrally extending from said supporting portion in a first direction and disposed close to a front side of the photovoltaic cell laminate and a second connecting portion integrally extending from said supporting portion in a second direction opposite to said first direction and close to a back side of the photovoltaic cell laminate. When a plurality of photovoltaic modules are mounted onto the installation surface, the first connecting portion of one photovoltaic module is overlappingly connected with the second connecting portion of another adjacent photovoltaic module so that a relative position of the photovoltaic module and another adjacent photovoltaic module is maintained and the plurality of photovoltaic modules are mounted onto the installation surface.

By means of the support being disposed at the back surface of the photovoltaic cell laminate, the present invention can do without traditional heavy frame and needs only a much simpler structure, whereby the weight of the photovoltaic module is significantly reduced. Moreover, the opposite ends of the support are designed to have the first connecting portion and the second connecting portion which can cooperate with each other and can be locked together by means of cooperation between the first connecting portion and the second connecting portion, in such a manner, adjacent two photovoltaic modules are connected in a front-to-back direction without an additional connector structure. Such an end-to-end mode of connection is very simple and easy to operate, whereby the assembly procedure of the photovoltaic module is simplified to a great extent and the working efficiency is improved.

Preferably, when a plurality of photovoltaic modules is stacked, the support of one photovoltaic module is supported on the support of another adjacent photovoltaic module, and the photovoltaic cell laminate of each photovoltaic module is not extruded by other photovoltaic modules in stack. By disposing such a supporting structure in an upper-to-bottom stack on the support of the photovoltaic module, the present invention can effectively ensure the stability of the photovoltaic modules in stack and facilitate the transportation of the photovoltaic modules.

Preferably, the support comprises a first upper restricting portion, a first lower restricting portion, a second upper restricting portion and a second lower restricting portion. The first upper restricting portion and the first lower restricting portion are configured to be beyond the front side of the photovoltaic cell laminate, and the second upper restricting portion and the second lower restricting portion are configured to be beyond the back side of the photovoltaic cell laminate. When a plurality of photovoltaic modules are stacked, the first upper restricting portion of one photovoltaic module leans against the first lower restricting portion of another adjacent photovoltaic module, and the second upper restricting portion of one photovoltaic module leans against the second lower restricting portion of another photovoltaic module, so that movement of the photovoltaic module relative to another adjacent photovoltaic module in a front-to-back direction is restricted. Further, by disposing the first upper restricting portion, the first lower restricting portion, the second upper restricting portion and the second lower restricting portion, and by means of cooperation and restriction between the first upper restricting portion and the first lower restricting portion, as well as cooperation and restriction between the second upper restricting portion and the second lower restricting portion, the present invention can effectively restrict a relative movement of the photovoltaic modules in a front-to-back direction, thereby facilitating the transportation of the photovoltaic modules.

Preferably, the support further comprises a third upper restricting portion and a third lower restricting portion. When a plurality of photovoltaic modules is stacked, the third upper restricting portion of one photovoltaic module cooperates with the third lower restricting portion of another adjacent photovoltaic module, so that movement of the photovoltaic module relative to another adjacent photovoltaic module in a left-to-right direction is restricted. Further, by disposing the third upper restricting portion and the third lower restricting portion, and by means of cooperation and restriction between the third upper restricting portion and the third lower restricting portion, the photovoltaic module located at the upper in the present invention can better protect the photovoltaic module located at the lower, and can effectively restrict a relative movement of the photovoltaic modules in a left-to-right direction, thereby further facilitating the transportation of the photovoltaic modules.

Other aspects and features of the present invention will become more evident by referring to detailed descriptions of the accompanying drawings hereinafter. But it should be made clear that the accompanying drawings are provided for the purpose of explanation, rather than limiting the scope of the invention, as the scope of the invention should be limited in the attached claims. It should also be made clear that unless it is clearly stated, the drawings are not drawn to scale; they are only intended to conceptually illustrate the structures and processes described herein.

### BRIEF DESCRIPTION OF THE DRAWINGS

FIG. 1 is an exploded, perspective view of a portion of a photovoltaic system in accordance with an embodiment of the present invention;

FIG. 2 is a perspective view of a photovoltaic module of FIG. 1;

FIG. 3 is a side view of the photovoltaic module of FIG. 2;

FIG. 4 is a cross-sectional view of FIG. 2 taken along line A-A;

FIG. 5 is a perspective view of a support of FIG. 2;

FIG. 6 is a perspective view of the support similar to FIG. 5, but illustrating another angle of view;

FIG. 7 and FIG. 8 are respectively enlarged schematic views of a portion of a photovoltaic module in accordance with an embodiment of the present invention before and after assembly in a front-to-back arrangement;

FIG. 9 is a schematic view of a photovoltaic module provided with ballasts in accordance with the present invention;

FIG. 10 is a perspective view of the ballast of FIG. 9 from another angle of view;

FIG. 11 is a perspective view of a middle wind deflector of FIG. 1 from another angle of view;

FIG. 12 is a perspective view of an exterior wind deflector of FIG. 1 from another angle of view;

FIG. 13 is a top view of two of photovoltaic modules in stack in accordance with the present invention;

FIG. 14 is a side view of the photovoltaic modules in stack of FIG. 13;

FIG. 15 is a cross-sectional view of FIG. 13 taken along line B-B;

FIG. 16 and FIG. 17 are respectively enlarged views of local regions D and E of FIG. 15; and

FIG. 18 is a cross-sectional view of FIG. 13 taken along line C-C.

### DETAILED DESCRIPTION OF THE DRAWINGS

Hereinafter, detailed descriptions will be given to the embodiments of the present invention in combination with the attached drawings in order to make the above objectives, features and advantages of the present invention more evident.

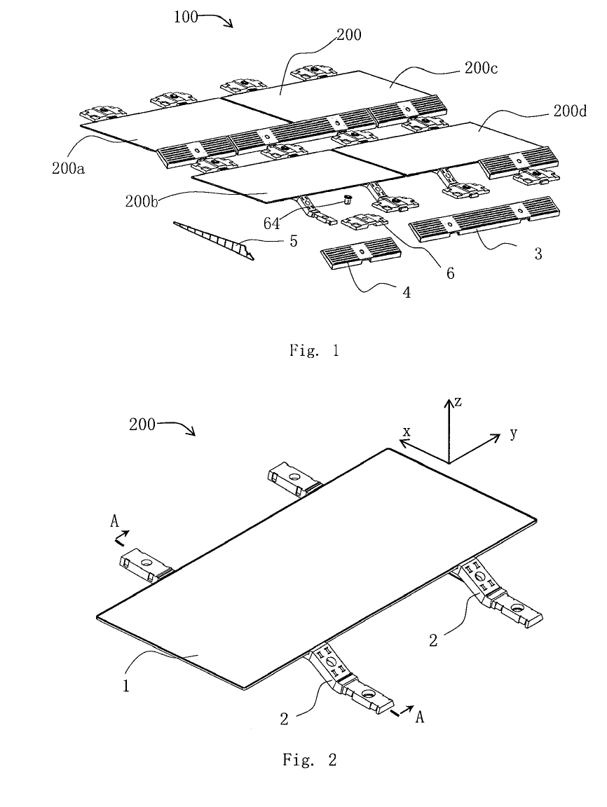

With reference to FIG. 1, a photovoltaic system 100 in accordance with an embodiment of the present invention is adapted to be mounted onto an installation surface (not shown) of a building, such as a surface of rooftop, and comprises a plurality of photovoltaic modules 200, and middle wind deflectors 3, exterior wind deflectors 4 and lower wind deflectors 5 which are mounted onto the photovoltaic modules 200. The middle wind deflector 3 and the exterior wind deflector 4 constitute a wind deflector structure for a photovoltaic system in accordance with the present invention. Since the wind deflector structure for photovoltaic system composed of the middle wind deflector 3 and the exterior wind deflectors 4 is mounted to a back side of the photovoltaic module 200, the wind deflector structure for photovoltaic system in accordance with the present invention is also referred to as a back wind deflector. The plurality of photovoltaic modules 200 form an array arranged in rows and columns. In a specific embodiment, the four photovoltaic modules 200 arranged in two rows and in two columns, i.e., a first photovoltaic module 200a, a second photovoltaic module 200b, a third photovoltaic module 200c and a fourth photovoltaic module 200d are taken as an example for schematic illustration, but they are not intended to limit the present invention. Actually, depending on a size of the installation surface of the building, the photovoltaic system 100 according to the present invention can select a plurality of photovoltaic modules 200 arranged in any arrayed form.

Referring to FIG. 2, the photovoltaic module 200 comprises a photovoltaic cell laminate 1 and a support 2 mounted onto the photovoltaic cell laminate 1. The support 2 is adapted to be mounted onto the installation surface of the building, and includes a supporting portion 20 defining a support face for supporting a back surface of the photovoltaic cell laminate 1. Preferably, the photovoltaic module 200 comprises at least two supports 2. The supports 2 are in a longitudinal shape extending in a front-to-back direction, and are spaced in a left-to-right direction arranged side by side in the back surface of the photovoltaic cell laminate 1. In a specific embodiment, a pair of supports 2 is disposed separately in the back surface of the photovoltaic cell laminate 1.

The photovoltaic cell laminate 1 of the present invention is formed by laminating, and encapsulating a front glass substrate, sealant, a plurality of solar cells and a back panel and then by edge sealing. The edge sealing is achieved by means of sealant and/or mounting a sealing frame in a perimeter thereof. The back panel of the photovoltaic cell laminate may also be a glass substrate. Since the frame of the photovoltaic cell laminate of the present invention is only for seal, in comparison to a traditional photovoltaic module, the frame of the photovoltaic cell laminate of the present invention is simple in structure, and there is no need for the frame to be designed as a fixing member for mounting the photovoltaic system; as the frame is light in weight, it can significantly reduce the weight of the photovoltaic cell laminate 1 and easily meet the requirements of related standards for the maximum weight of the photovoltaic module of roof.

Orientation terms mentioned in the application, such as “front”, “back”, “top”, “bottom”, “upper”, “lower”, “left”, “right” and etc., are only for describing a relative positional relationship between the individual members, but are not intended to limit an absolute orientation of related members. Referring to FIG. 2, the positive x-axis represents the front, and the negative x-axis represents the back; the positive y-axis represents the left, and the negative y-axis represents the right; and the positive z-axis represents the upper, and the negative z-axis represents the lower.

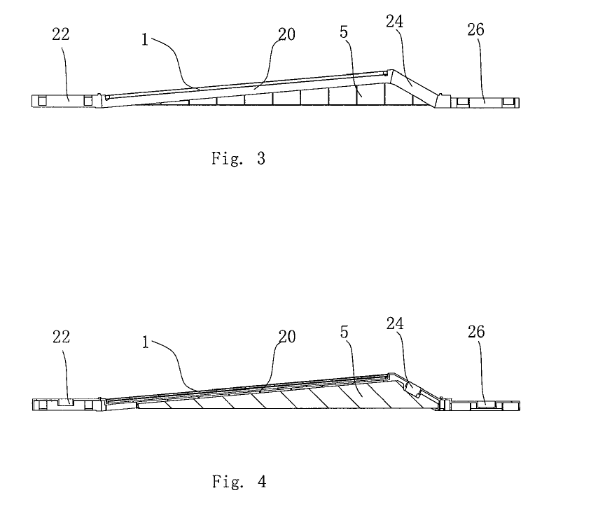

With reference to FIGS. 3 to 6, the support 2 comprises a supporting portion 20, a first connecting portion 22, a transition portion 24 and a second connecting portion 26. Preferably, the supporting portion 20 is affixed to the back surface of the photovoltaic cell laminate 1 by adhesive for supporting the photovoltaic cell laminate 1. The supporting portion 20 has a receiving groove 202 at a side thereof for affixing the photovoltaic cell laminate 1. The first connecting portion 22 extends forwardly from a front end of the supporting portion 20, and is disposed close to a front side of the photovoltaic cell laminate 1. The transition portion 24 extends backwardly from a back end of the supporting portion 20 and is adapted for connecting the supporting portion 20 and the second connecting portion 26. The second connecting portion 26 further extends backwardly from the transition portion 24, and is disposed close to a back side of the photovoltaic cell laminate. In one embodiment, the first connecting portion 22 extends from a first end of the supporting portion 20 beyond the front side of the photovoltaic cell laminate 1. The transition portion 24 and the second connecting portion 26 extend from an opposite second end of the supporting portion 20 beyond the back side of the photovoltaic cell laminate 1.

When the photovoltaic module 200 is mounted onto the installation surface of the building, the first connecting portion 22 and the second connecting portion 26 are placed on the installation surface for cooperation with the installation surface. The supporting portion 20 is disposed at a certain angle to the installation surface so that the photovoltaic cell laminate 1 is also at a certain angle to the installation surface after assembled. Such a tilting arrangement of the photovoltaic cell laminate 1 will be helpful for collecting solar energy by the photovoltaic cell laminate 1 and for better converting sunlight into electricity and for making effective use of area of the installation surface such as rooftop. Factors such as power conversion and effective use of installation area should be taken into consideration in arranging an angle between the photovoltaic cell laminate 1 and the installation surface such that, the photovoltaic modules will not be shielded from each other when the sunlight is shining. The angle is preferably in a range of 5-20°. In one embodiment, the first connecting portion 22 and the second connecting portion 26 are located on the same horizontal surface.

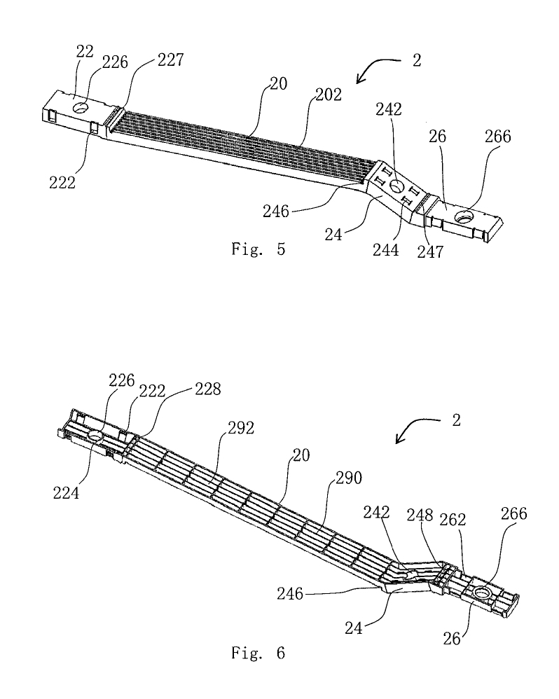

Mainly referring to FIGS. 5 to 8, when a plurality of photovoltaic modules 200 is mounted end to end (i.e., in a front-to-back direction) onto the installation surface, the first connecting portion 22 of one photovoltaic module 200 is engaged with the second connecting portion 26 of another adjacent photovoltaic module 200 so that a relative position of the photovoltaic module 200 and another adjacent photovoltaic module 200 is maintained. The first connecting portion 22 and the second connecting portion 26 of the present invention are arranged to be a structure that can cooperate and lock with each other. In a specific embodiment of the present invention, the first connecting portion 22 and the second connecting portion 26 both are in a frame shape, and the first connecting portion 22 is sized to be greater than the second connecting portion 26 so that the first connecting portion 22 can cover the second connecting portion 26. The first connecting portion 22 has a first fixing portion 222 disposed thereon, and the second connecting portion 26 has a second fixing portion 262 disposed thereon and corresponding to the first fixing portion 222 of the first connecting portion 22. Preferably, the first connecting portion 22 comprises at least two first fixing portions 222, and the second connecting portion 26 comprises the second fixing portions 262 having at least the same number corresponding to the number of the first fixing portions 222. The first fixing portions 222 are respectively disposed at the opposite sides of the first connecting portion 22, and the second fixing portions 262 are respectively disposed at the opposite sides of the second connecting portion 26. At least one of the first fixing portion 222 and the second fixing portion 262 is a resilient structure. When the first connecting portion 22 of one photovoltaic module 200 is engaged with the second connecting portion 262 of another adjacent photovoltaic module 200, the resilient structure is first pressed by the other of the first fixing portion 222 and the second fixing portion 262 and is deformed resiliently, and then the resilient structure is returned resiliently due to release of the press and is thus locked. The first fixing portion 222 and the second fixing portion 262 cooperate and lock with each other so that a relative position of the first fixing portion 222 and the second fixing portion engaged is restricted. In one embodiment, the first fixing portion 222 is configured to be bumps projecting inwardly from lower edges of apertures of opposite two side walls, and the second fixing portion 262 is configured to be resilient tabs deflected outwardly from opposite two side walls. The resilient tabs are locked with the bumps of the lower edges of the apertures. The first connecting portion 22 has a protrusion 224 protruding downwardly from a top thereof. A first mounting hole 226 is defined through the protrusion 224. The second connecting portion 26 defines a second mounting hole 266 corresponding to the protrusion 224. When the first connecting portion 22 of one photovoltaic module 200 is engaged with the second connecting portion 26 of another adjacent photovoltaic module 200, the protrusion 224 of the first connecting portion 22 of the photovoltaic module 200 is inserted into the second mounting hole 266 of another adjacent photovoltaic module 200, and the first mounting hole 226 is aligned with the second mounting hole 266.

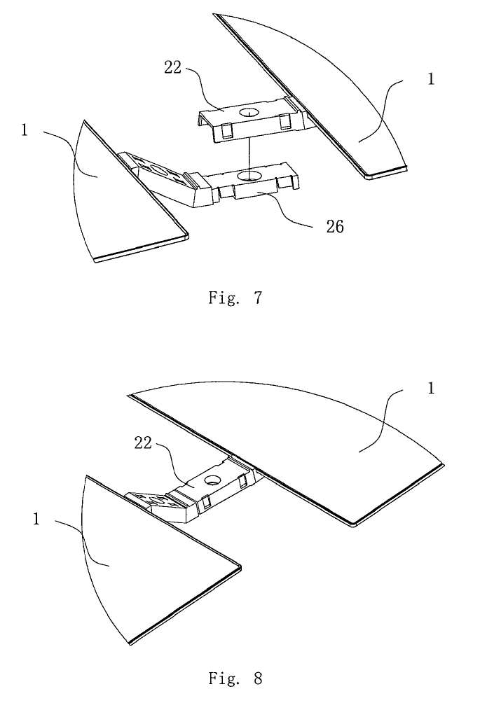

The support 2 of the photovoltaic module 200 in accordance with the present invention is designed to have the first connecting portion 22 and the second connecting portion 26 which can cooperate with each other and can be locked together by means of cooperation between the first connecting portion 22 and the second connecting portion 26 of adjacent two photovoltaic modules 200, in such a manner, it can be realized that the adjacent two photovoltaic modules 200 are connected in a front-to-back direction without an additional connector structure. As shown in FIG. 7 and FIG. 8, when adjacent two photovoltaic modules 200 are required to be connected in a front-to-back direction, the first connecting portion 22 of the support 2 of one photovoltaic module 200 covers the second connecting portion 26 of the support 2 of another adjacent photovoltaic module 200. The protrusion 224 of the first connecting portion 22 is received in the second mounting hole 266 of the second connecting portion 26, and the second mounting hole 266 is aligned with the first mounting hole 226. The second fixing portion 262 of the second connecting portion 26 may lock in the first fixing portion 222 of the first connecting portion 22 so that the first connecting portion 22 and the second connecting portion 26 are locked with each other, thereby realizing a connection in a front-to-back direction between adjacent two photovoltaic modules 200. For connecting more photovoltaic modules 200 in a front-to-back direction, a similar connecting manner above can be adopted for connection. The end-to-end mode of connection is very simple and easy to operate, whereby the assembly procedure of the photovoltaic system 100 is simplified to a great extent and the working efficiency is improved.

The above is described by taking an example in which both the first connecting portion 22 and the second connecting portion 26 are in a frame shape, but the present invention is not limited to the example herein. The first connecting portion 22 and the second connecting portion 26 of the present invention can also adopt other structures which can cooperate and lock with each other without departing from the spirit of the present invention. Furthermore, in an alternative embodiment of the present invention, it can be also adopted that the second connecting portion 26 is sized to be greater than the first connecting portion 22 so that the second connecting portion 26 covers the first connecting portion 22. These can also achieve the objectives of the present invention. In a further embodiment of the present invention, the first fixing portion 222 of the first connecting portion 22 and the second fixing portion 262 of the second connecting portion 26 can be also disposed in reverse or can adopt other locking manner. All of these equivalent substitutions and deformations are covered in the protective scope of the present invention.

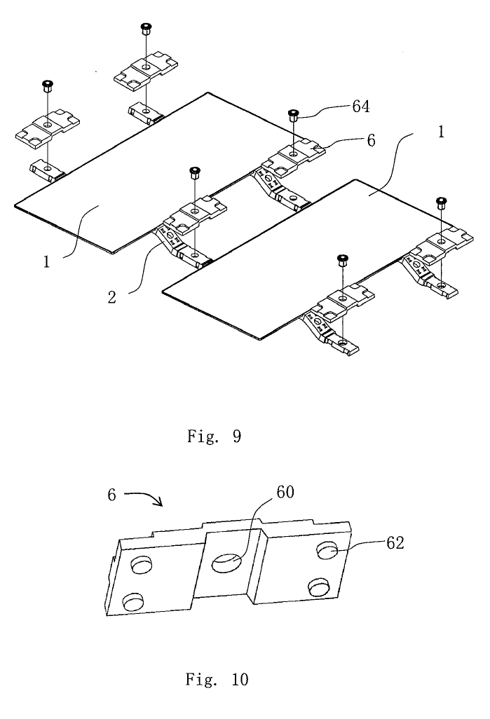

See FIG. 9 and FIG. 10, in an alternative embodiment of the present invention, optionally, the photovoltaic system 100 may further comprise a plurality of ballasts 6 in order to increase reliability of the photovoltaic module on the installation surface such as a rooftop depending on the local climate. The ballast 6 is pressed on the first connecting portion 22 and the second connecting portion 26 which are connected to each other. The ballast 6 defines a mounting hole 60 corresponding to the first mounting hole 226 of the first connecting portion 22 and/or the second mounting hole 266 of the second connecting portion 26.

When a plurality of photovoltaic modules 200 is mounted onto the installation surface, and the first connecting portion 22 of one photovoltaic module is engaged with the second connecting portion 26 of another adjacent photovoltaic module, for an engaged portion of the photovoltaic modules in a front-to-back direction, since the first connecting portion 22 of one photovoltaic module covers the second connecting portion 26 of another adjacent photovoltaic module, the ballast 6 is fixed on a location where the first connecting portion 22 and the second connecting portion 26 are engaged via a pin 64 sequentially passing through the mounting hole 60 of the ballast 6, the first mounting hole 226 of the first connecting portion 22 and the second mounting hole 266 of the second connecting portion 26. For the photovoltaic module 200 at one outmost end of array of the photovoltaic system, the ballast 6 is fixed on the first connecting portion 22 via a pin 64 sequentially passing through the mounting hole 60 of the ballast 6 and the first mounting hole 226 of the first connecting portion 22. For the photovoltaic module 200 at the other outmost end thereof, the ballast 6 is fixed on the second connecting portion 26 via a pin 64 sequentially passing through the mounting hole 60 of the ballast 6 and the second mounting hole 266 of the second connecting portion 26. Preferably, in order that the ballast 6 may better support on the surface of the building, the ballast 6 further provides a plurality of supporting posts 62 at the bottom thereof for support on the installation surface of the building.

During assembly of the photovoltaic system 100, for the purpose of preventing wind from affecting stability of the whole photovoltaic system, it is usually required to install wind deflectors to change the flow of wind. As shown in FIG. 1, when the photovoltaic module 200 is mounted onto the installation surface, the back wind deflector 3, 4 is mounted close to the back side of the photovoltaic cell laminate 1, and substantially shields a space between the back side of the photovoltaic module 200 and the installation surface. In view of the issue of the cooling of the photovoltaic module, the back wind deflector 3, 4 defines a plurality of openings 30, 40. The openings 30, 40 may be round or polygonal through holes, or may also be shutter holes in an alternative preferred embodiment so that this will not only allow the cooling of the photovoltaic modules 200, but also not affect the function of deflecting wind. The back wind deflector 3, 4 is fixed onto the supports 2 of at least two photovoltaic modules 200 side by side in a left-to-right direction so as to restrict a relative position of the at least two adjacent photovoltaic modules 200 in a left-to-right direction. In detail, the back wind deflector 3, 4 is fixed onto the transition portions 24 of the supports 2 of adjacent photovoltaic modules 200 so that the adjacent photovoltaic modules 200 are connected together side by side.

In conjunction with FIGS. 1 and 11 to 12, the back wind deflector 3, 4 includes a middle wind deflector 3 and an exterior wind deflector 4. The middle wind deflector 3 has a length substantially equal to that of the back side of the photovoltaic cell laminate 1, and is adapted for side by side connection adjacent two photovoltaic modules 200 in a left-to-right direction. The middle wind deflector 3 defines a pair of notches 32 corresponding to adjacent transition portions 24 of two photovoltaic modules 200 in a side-by-side arrangement. The transition portion 24 may be received in the notch 32. The transition portion 24 defines a positioning hole 242 and a plurality of fixing holes 244 (as shown in FIG. 5) thereon. The middle wind deflector 3 provides in the notch 32 a plurality of hooks 36 projecting and corresponding to the fixing holes 244. The plurality of hooks 36 are respectively locked in the plurality of fixing holes 244. The middle wind deflect 3 provides a positioning post 34 projecting and corresponding to the positioning hole 242, and the positioning post 34 may be positioned in the positioning hole 242. An abdication portion 246 for receiving an upper side of the middle wind deflector 3 is disposed at a top of a junction of the supporting portion 20 and the transition portion 24.

Returning to FIG. 1, when adjacent two photovoltaic modules 200 such as the first photovoltaic module 200a and the third photovoltaic module 200c, are required to be connected side by side in a left-to-right direction, the transition portion 24 of the supporting portion 20 of the first photovoltaic module 200a and the transition portion 24 of the supporting portion 20 of the third photovoltaic module 200c are respectively received in a pair of notches 32 of the same middle wind deflector 3. The positioning post 34 of the middle wind deflector 3 is first positioned in the positioning hole 242 so that the middle wind deflector 3 is first positioned in the first photovoltaic module 200a and the third photovoltaic module 200c, then the hooks 36 of the middle wind deflector 3 are locked in the fixing holes of the transition portion 24, and the upper side of the middle wind deflector 3 is locked in the abdication portion 246 of the support 2 so that the middle wind deflector 3 is fixed on the adjacent two transition portions 24 of the first photovoltaic module 200a and the third photovoltaic module 200c in a side-by-side arrangement. Therefore, the adjacent first photovoltaic module 200a and third photovoltaic module 200c are connected side by side by means of the middle wind deflector 3. For a side-by-side connection between the second photovoltaic module 200b and the fourth photovoltaic module 200d, or even for side by side connecting more photovoltaic modules 200, a similar connecting manner above may be adopted for connection. As shown in FIG. 1, the photovoltaic modules 200 are arranged in an array form by the front-to-back connection and the side-by-side connection of the photovoltaic modules 200 above-mentioned.

By cleverly using the middle wind deflector 3 and by means of cooperation and lock between the middle wind deflector 3 and adjacent two transition portions 24 of adjacent two photovoltaic modules 200, the present invention can achieve the side-by-side connection of any number of photovoltaic modules 200 in a left-to-right direction without an additional connector structure. Thus, the side-by-side connection in a left-to-right direction of the present invention have such advantages as being simple and rapid, thereby greatly saving the assembly procedure and the number of parts of the photovoltaic system 100 and improving the working efficiency. The middle wind deflector 3 according to the present invention has dual functions, that is, on the one hand, the middle wind deflector 3 may perform general functions as a wind deflector in preventing an array of the photovoltaic system from the impacts of wind blows so that the array of photovoltaic system may be stably retained on the installation surface; on the other hand, it functions as a connector structure for side by side connecting the photovoltaic modules 200 so that additional connectors may be omitted upon the side-by-side connection, thereby saving the number of the parts and reducing the cost for the photovoltaic system 100.

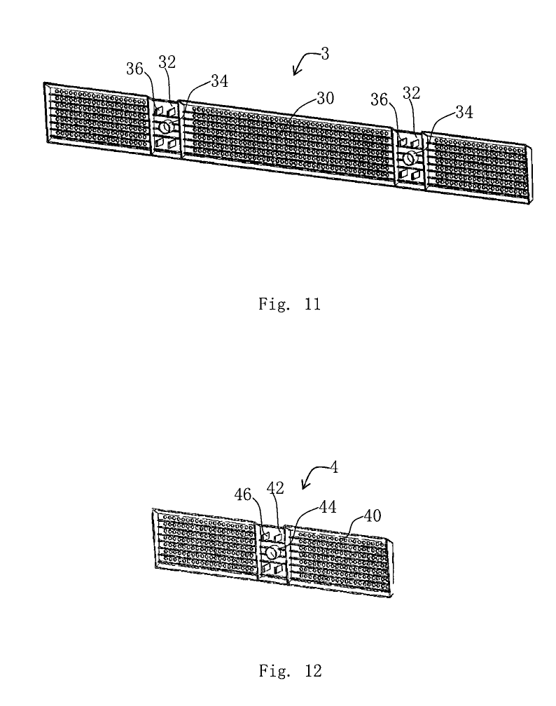

The exterior wind deflector 4 has a configuration similar to half of the middle wind deflector 3. In conjunction with FIG. 12, the exterior wind deflector 4 defines a notch 42 corresponding to the transition portion 24 of the support of the photovoltaic module 200. The exterior wind deflector 4 provides in the notch 42 a plurality of hooks 46 projecting and corresponding to the fixing holes 244 of the transition portion 24, and a positioning post 44 projecting and corresponding to the positioning hole 242 of the transition portion 24. In conjunction with FIG. 1, the exterior wind deflector 4 is installed close to an outer end of the back side of the photovoltaic module 200 located at the outmost end thereof. The transition portion 24 of the supporting portion 20 of the photovoltaic module 200 located at the outmost end thereof is received in the notch 42 of the exterior wind deflector 4, and the positioning post 44 of the exterior wind deflector 4 is positioned in the positioning hole 242 of the transition portion 24, so that the exterior wind deflector 4 is first positioned in the photovoltaic module 200 located at the outmost end thereof, and the hooks of the exterior wind deflector 4 are further locked in the fixing holes 244 of the transition portion 24. The exterior wind deflector 4 is thus fixed on the transition portion 24 of the outmost side of the photovoltaic module 200 at the outmost end thereof.

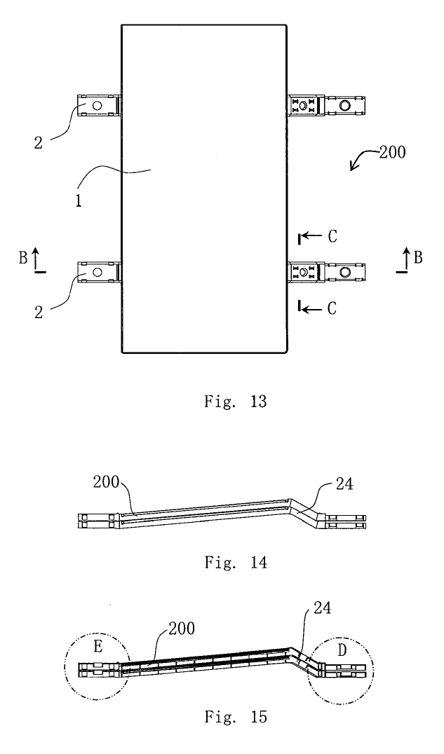

In conjunction with FIGS. 13 to 18, when a plurality of photovoltaic modules 200 is placed or transported in stack, the support 2 of one photovoltaic module 200 can support on the support 2 of another adjacent photovoltaic module 200, and the photovoltaic cell laminate 1 of each of the photovoltaic modules 200 is not extruded by other photovoltaic modules 200 in stack.

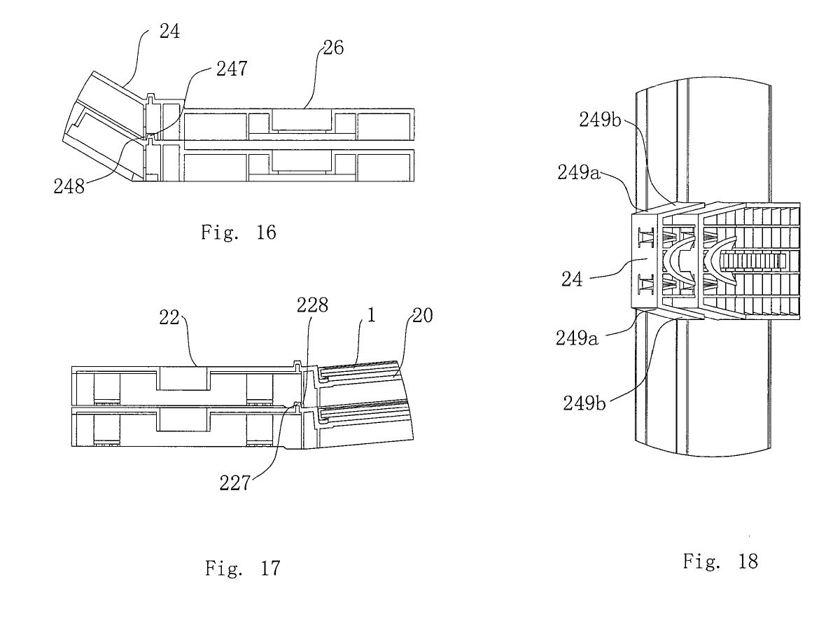

In conjunction with FIGS. 16 to 18, FIG. 16 and FIG. 17 are respectively enlarged views of local regions D and E of FIG. 15, and FIG. 18 is a cross-sectional view of FIG. 13 taken along line C-C. The support comprises a first upper restricting portion 227, a first lower restricting portion 228, a second upper restricting portion 247 and a second lower restricting portion 248. The first upper restricting portion 227 and the first lower restricting portion 228 are configured to be beyond the front side of the photovoltaic cell laminate 1, and the second upper restricting portion 247 and the second lower restricting portion 248 are configured to be beyond the back side of the photovoltaic cell laminate 1. The first upper restricting portion 227 and the first lower restricting portion 247 are close to a junction of the first connecting portion 22 and the supporting portion 20, and the second upper restricting portion 228 and the second lower restricting portion 248 are close to a junction of the second connecting portion 26 and the transition portion 24. The first upper restricting portion 227 and the second upper restricting portion 247 are disposed at a top of the support 2. The first upper restricting portion 227 has a backward restricting surface and the second upper restricting portion 247 has a forward restricting surface. The first lower restricting portion 228 and the second lower restricting portion 248 are disposed at a bottom of the support 2. The first lower restricting portion 228 has a forward restricting surface and the second lower restricting portion 248 has a backward restricting surface. In one embodiment, the first upper restricting portion 227 and the second upper restricting portion 247 are represented by restricting projections projecting upwardly from the top, and the first lower restricting portion 228 and the second lower restricting portion 248 are represented by stiffening ribs extending in a left-to-right direction from the bottom.

As shown in the enlarged, local views of FIG. 17 and FIG. 18, when a plurality of photovoltaic modules 200 is stacked, the first upper restricting portion 227 of one photovoltaic module 200 leans against the first lower restricting portion 228 of another adjacent photovoltaic module 200. In detail, the restricting surface of the first upper restricting portion 227 of one photovoltaic module 200 leans against the restricting surface of the first lower restricting portion 228 of another adjacent photovoltaic module 200. The second upper restricting portion 247 of one photovoltaic module 200 leans against the second lower restricting portion 248 of another adjacent photovoltaic module 200. In detail, the restricting surface of the second upper restricting portion 247 of one photovoltaic module 200 leans against the restricting surface of the second lower restricting portion 248 of another adjacent photovoltaic module 200. Therefore, movement of the photovoltaic module 200 relative to another adjacent photovoltaic module 200 in a front-to-back direction is restricted, i.e., a relative movement in an end-to-end direction is restricted, thereby facilitating the transportation of the photovoltaic modules 200.

Referring particularly to FIG. 18, the support 2 further comprises a third upper restricting portion 249a and a third lower restricting portion 249b. When a plurality of photovoltaic modules 200 is stacked, the third upper restricting portion 249a of one photovoltaic module 200 cooperates with the third lower restricting portion 249b of another adjacent photovoltaic module 200, so that movement of the photovoltaic module 200 relative to another adjacent photovoltaic module 200 in a left-to-right direction is restricted. In a specific embodiment, left and right sides of the transition portion 24 form a shape which is narrow at an upper thereof and is wide at a lower thereof. The uppers of the left and right sides of the transition portion 24 form the upper stopping wall and the left and right sides of the transition portion 24 extend downwardly to form the lower stopping wall. When the third upper restricting portion 249a of one photovoltaic module 200 cooperates with the third lower restricting portion 249b of another adjacent photovoltaic module 200, outer sides of the uppers (i.e., the upper stopping wall) of the left and right sides of the transition portion 24 cooperate with inner sides of the lowers (i.e., the lower stopping wall) of the left and right sides of the transition portion 24, so that the photovoltaic module 200 located at the upper can protect photovoltaic module 200 located at the lower, and the movement of the photovoltaic module 200 relative to another adjacent photovoltaic module 200 in a left-to-right direction is prevented, thereby further facilitating the transportation of the photovoltaic modules 200.

Preferably, in conjunction with FIG. 6, the support 2 has a plurality of stiffening ribs 290 extending in a front-to-back direction at a side thereof far from the photovoltaic cell laminate 1 and defines a receiving slot 292 located among the plurality of stiffening ribs. The stiffening ribs 290 are adapted for strengthening the photovoltaic module 200. As shown in FIG. 4, the lower wind deflector 5 of the photovoltaic system 100 is mounted in the receiving slot 292. As shown in FIG. 1, after the photovoltaic modules 200 are assembled in a required array form, the lower wind deflector 5 is installed in a lower of the photovoltaic module 200 located in the outmost side thereof, and the lower wind deflector 5 is installed in the receiving slot 292 of the support 2 of the photovoltaic module 200 located in the outmost side thereof.

Although the present invention is disclosed by the preferable embodiments as discussed above, these embodiments are not intended to be limiting, and potential variations and modifications can be made by any one skilled in the art without departing from the spirit and scope of the present invention, so the protective scope of the present invention should cover all as defined in the attached claims.

What is claimed:

1. A photovoltaic module comprising:
a photovoltaic cell laminate, and
a support adapted to be mounted onto an installation surface,
wherein the support includes a supporting portion defining a support face for supporting a back surface of the photovoltaic cell laminate, a first connecting portion integrally extending from said supporting portion in a first direction and close to a front side of the photovoltaic cell laminate, and a second connecting portion integrally extending from said supporting portion in a second direction opposite to said first direction and disposed close to a back side of the photovoltaic cell laminate, and when a plurality of photovoltaic modules is mounted onto the installation surface, the first connecting portion of one photovoltaic module is overlappingly connected with the second connecting portion of another adjacent photovoltaic module so that a relative position of the photovoltaic module and another adjacent photovoltaic module is maintained and the plurality of photovoltaic modules is mounted onto the installation surface.

2. The photovoltaic module according to claim 1, wherein the first connecting portion has a first fixing portion, the second connecting portion has a second fixing portion corresponding to the first fixing portion, the first fixing portion and the second fixing portion cooperate with each other and are locked so that the first connecting portion of one photovoltaic module is engaged with the second connecting portion of another adjacent photovoltaic module and a relative position of the first and second connecting portions engaged is restricted.

3. The photovoltaic module according to claim 2, comprising at least two first fixing portions and the second fixing portions having at least the same number corresponding to the number of the first fixing portions, and wherein the first fixing portions are respectively disposed at opposite sides of the first connecting portion, the second fixing portions are respectively disposed at opposite sides of the second connecting portion, at least one of the first and second fixing portions is a resilient structure, and when the first connecting portion of one photovoltaic module is engaged with the second connecting portion of another adjacent photovoltaic module, the resilient structure is first pressed by the other of the first and second fixing portions and is deformed resiliently, then the resilient structure is returned resiliently due to release of the press and is thus locked.

4. The photovoltaic module according to claim 1, wherein the first connecting portion has a protrusion protruding downwardly from a top side thereof, the second connecting portion defines a second mounting hole corresponding to the protrusion, and when the first connecting portion of one photovoltaic module is engaged with the second connecting portion of another adjacent photovoltaic module, the protrusion of the first connecting portion of the photovoltaic module is inserted into the second mounting hole of another adjacent photovoltaic module.

5. The photovoltaic module according to claim 4, wherein a first mounting hole is defined through the protrusion of the first connecting portion.

6. The photovoltaic module according to claim 1, wherein the support further comprises a transition portion connecting the supporting portion and the second connecting portion, and when the photovoltaic module is mounted onto the installation surface, the first connecting portion and the second connecting portion cooperate with the installation surface while the supporting portion and the transition portion are tilted relative to the installation surface so that the photovoltaic cell laminate is mounted tiltedly with its front side close to the installation surface and its back side far from the installation surface.

7. The photovoltaic module according to claim 6, wherein the supporting portion has a receiving groove at a side thereof for affixing the photovoltaic cell laminate.

8. The photovoltaic module according to claim 1, wherein each of the photovoltaic modules comprises at least two supports, and the at least two supports are in a longitudinal shape extending in a front-to-back direction and are arranged separately in a left-to-right direction at the back surface of the photovoltaic cell laminate.

9. The photovoltaic module according to claim 1, further comprising a ballast, and wherein when the plurality of photovoltaic modules is mounted onto the installation surface and the first connecting portion of one photovoltaic module is engaged with the second connecting portion of another adjacent photovoltaic module, the ballast is fixed on a location where the first connecting portion and the second connecting portion are engaged.

10. The photovoltaic module according to claim 9, wherein a mounting hole is defined in the ballast, and the ballast is fixed on a location where the first connecting portion and the second connecting portion are engaged via a pin extending through the mounting hole.

11. The photovoltaic module according to claim 10, wherein the ballast has a plurality of supporting posts at the bottom thereof, and when the photovoltaic module is mounted onto the installation surface, the supporting posts are supported on the installation surface.

12. The photovoltaic module according to claim 6, wherein when the plurality of photovoltaic modules is stacked, the support of one photovoltaic module is supported on the support of another adjacent photovoltaic module, and the photovoltaic cell laminate of each photovoltaic module is not extruded by other photovoltaic modules in stack.

13. The photovoltaic module according to claim 12, wherein the support comprises a first upper restricting portion, a first lower restricting portion, a second upper restricting portion and a second lower restricting portion, the first upper restricting portion and the first lower restricting portion being configured to be beyond the front side of the photovoltaic cell laminate, and the second upper restricting portion and the second lower restricting portion being configured to be beyond the back side of the photovoltaic cell laminate, and wherein when the plurality of photovoltaic modules is stacked, the first upper restricting portion of one photovoltaic module leans against the first lower restricting portion of another adjacent photovoltaic module, and the second upper restricting portion of one photovoltaic module leans against the second lower restricting portion of another adjacent photovoltaic module so that movement of the photovoltaic module relative to another adjacent photovoltaic module in a front-to-back direction is restricted.

14. The photovoltaic module according to claim 13, wherein the first upper restricting portion and the second upper restricting portion are disposed at a top of the support, the first upper restricting portion having a backward restricting surface and the second upper restricting portion having a forward restricting surface, and the first lower restricting portion and the second lower restricting portion are disposed at a bottom of the support, the first lower restricting portion having a forward restricting surface and the second lower restricting portion having a backward restricting surface, and wherein when the plurality of photovoltaic modules is stacked, the restricting surface of the first upper restricting portion of one photovoltaic module leans against the restricting surface of the first lower restricting portion of another adjacent photovoltaic module, and the restricting surface of the second upper restricting portion of one photovoltaic module leans against the restricting surface of the second lower restricting portion of another adjacent photovoltaic module.

15. The photovoltaic module according to claim 13, wherein the first upper restricting portion and the first lower restricting portion are close to a junction of the first connecting portion and the supporting portion, and the second upper restricting portion and the second lower restricting portion are close to a junction of the second connecting portion and the transition portion.

16. The photovoltaic module according to claim 13, wherein the support further comprises a third upper restricting portion and a third lower restricting portion, and wherein when the plurality of photovoltaic modules is stacked, the third upper restricting portion of one photovoltaic module cooperates with the third lower restricting portion of another adjacent photovoltaic module so that movement of the photovoltaic module relative to another adjacent photovoltaic module in a left-to-right direction is restricted.

17. The photovoltaic module according to claim 16, wherein the third lower restricting portion comprises at least two lower stopping walls extending downwardly from left and right sides of the support respectively, and the third upper restricting portion comprises at least two upper stopping walls extending close to a top of the left and right sides of the support, and wherein when the third upper restricting portion of one photovoltaic module cooperates with the third lower restricting portion of another adjacent photovoltaic module, inner sides of the lower stopping wall of the third lower restricting portion are respectively stopped in left and right outer sides of the upper stopping wall of the third upper restricting portion.

18. The photovoltaic module according to claim 17, wherein the left and right sides of the transition portion form a shape which is narrow at an upper thereof and is wide at a lower thereof, the uppers of the left and right sides of the transition portion forming the upper stopping wall and the left and right sides of the transition portion extending downwardly to form the lower stopping wall, and when the third upper restricting portion of one photovoltaic module cooperates with the third lower restricting portion of another adjacent photovoltaic module, outer sides of the uppers of the left and right sides of the transition portion cooperate with inner sides of the lowers of the left and right sides of the transition portion so that movement of the photovoltaic module relative to another adjacent photovoltaic module in a left-to-right direction is prevented.

19. The photovoltaic module according to claim 1, wherein the support has a plurality of stiffening ribs extending in a front-to-back direction at a side thereof far from the photovoltaic cell laminate.

20. A support for a photovoltaic module adapted to be mounted onto an installation surface to support a photovoltaic cell laminate of a photovoltaic module, wherein the support defines a supporting portion adapted for supporting a back surface of the photovoltaic cell laminate and comprises a first connecting portion integrally extending from said supporting portion in a first direction and disposed close to a front side of the photovoltaic cell laminate and a second connecting portion integrally extending from said supporting portion in a second direction opposite to said first direction and close to a back side of the photovoltaic cell laminate, and wherein when a plurality of photovoltaic modules is mounted onto the installation surface, the first connecting portion of one photovoltaic module is overlappingly connected with the second connecting portion of another adjacent photovoltaic module so that a relative position of the photovoltaic module and another adjacent photovoltaic module is maintained and the plurality of photovoltaic modules is mounted onto the installation surface.

21. The support for the photovoltaic module according to claim 20, wherein the first connecting portion has a first fixing portion, the second connecting portion has a second fixing portion corresponding to the first fixing portion, the first fixing portion and the second fixing portion cooperate with each other and are locked so that the first connecting portion of one photovoltaic module is engaged with the second connecting portion of another adjacent photovoltaic module and a relative position of the first and second connecting portions engaged is restricted.

22. The support for the photovoltaic module according to claim 21, comprising at least two first fixing portions and the second fixing portions having at least the same number corresponding to the number of the first fixing portions, and wherein the first fixing portions are respectively disposed at opposite sides of the first connecting portion, the second fixing portions are respectively disposed at opposite sides of the second connecting portion, at least one of the first and second fixing portions is a resilient structure, and when the first connecting portion of one photovoltaic module is engaged with the second connecting portion of another adjacent photovoltaic module, the resilient structure is first pressed by the other of the first and second fixing portions and is deformed resiliently, and then the resilient structure is returned resiliently due to release of the press and is thus locked.

23. The support for the photovoltaic module according to claim 20, wherein the first connecting portion has a protrusion protruding downwardly from a top side thereof, the second connecting portion defines a second mounting hole corresponding to the protrusion, and when the first connecting portion of one photovoltaic module is engaged with the second connecting portion of another adjacent photovoltaic module, the protrusion of the first connecting portion of the photovoltaic module is inserted into the second mounting hole of another adjacent photovoltaic module.

24. The support for the photovoltaic module according to claim 23, wherein a first mounting hole is defined through the protrusion of the first connecting portion.

25. The support for the photovoltaic module according to claim 20, wherein the support further comprises a transition portion connecting the supporting portion and the second connecting portion, and when the photovoltaic module is mounted onto the installation surface, the first connecting portion and the second connecting portion cooperate with the installation surface while the supporting portion and the transition portion are tilted relative to the installation surface so that the front side of the photovoltaic cell laminate is mounted tiltedly with its front side close to the installation surface and its back side far from the installation surface.

26. The support for the photovoltaic module according to claim 25, wherein the supporting portion has a receiving groove at a side thereof for affixing the photovoltaic cell laminate.
